(19) United States
(12) Patent Application Publication
(10) Pub. No.: US 2011/0024719 A1
(43) Pub. Date: Feb. 3, 2011

(54) LARGE SCALE NANOELEMENT ASSEMBLY METHOD FOR MAKING NANOSCALE CIRCUIT INTERCONNECTS AND DIODES

(76) Inventors: Srinivas Sridhar, Newton, MA (US); Evin Gultepe, Boston, MA (US); Dattatri Nagesha, Allston, MA (US)

Correspondence Address: WEINGARTEN, SCHURGIN, GAGNEBIN & LEBOVICI LLP, TEN POST OFFICE SQUARE, BOSTON, MA, 02109, US

(21) Appl. No.: 12/936,938

(22) PCT Filed: Apr. 13, 2009
(86) PCT No.: PCT/US09/40346

§ 371 Date: Oct. 8, 2010

Related U.S. Application Data
(60) Provisional application No. 61/123,822, filed on Apr. 11, 2008.

(51) Int. Cl. H01L 29/66; H01L 21/3205; C25B 7/00; B82Y 40/00

(52) U.S. Cl. 257/9; 438/597; 204/477; 257/E29.166; 257/E21.294; 977/750; 977/742; 977/932; 977/842

(57) ABSTRACT

Nanoelements such as single walled carbon nanotubes are assembled in three dimensions into a nanoscale template on a substrate by means of electrophoresis and dielectrophoresis at ambient temperature. The current-voltage relation indicates that strong substrate-nanotube interconnects carrying mA currents are established inside the template pores. The method is suitable for large-scale, rapid, three-dimensional assembly of 1,000,000 nanotubes per square centimeter area using mild conditions. Circuit interconnects made by the method can be used for nanoscale electronics applications.

### CROSS REFERENCE TO RELATED APPLICATIONS

This application claims the priority of U.S. Provisional Application No. 61/123,822 filed Apr. 11, 2008 entitled, LARGE SCALE 3D VERTICAL ASSEMBLY OF SINGLE-WALLED CARBON NANOTUBES AT AMBIENT TEMPERATURES IN NANOPOROUS TEMPLATES, the whole of which is hereby incorporated by reference.

### STATEMENT REGARDING FEDERALLY SPONSORED RESEARCH

The research leading to this invention was carried out with U.S. Government support provided under grants from the National Science Foundation (NSF-0504331 and NSF-0425826). The U.S. Government has certain rights in the invention.

### BACKGROUND OF THE INVENTION

Single walled carbon nanotubes (SWNT) have attracted a great deal of attention for applications in nanoscale electronics. They have tremendous importance as interconnects, since conventional conductors (e.g., copper wires) fail to meet the required resistivity for smaller diameters (Cho et al.). Recent discoveries have demonstrated that SWNT have a large current capacity, as high as 10⁹ A cm⁻² (Yao et al.), or a mobility as high as 100,000 cm²/Vs (Durkop et al.).

A key challenge in utilizing SWNT and other nanoelements in nanoscale electronics is to develop their application in large scale devices. Available approaches in SWNT-related manufacturing are mainly divided into two types: growing SWNT into a device, and assembling prefabricated SWNT into a device. All methods of growing SWNT require high temperature synthesis (Bethune et al., Kong et al.), and in most methods nanotubes need a post process for cleaning, cutting and sorting to reach a narrow size distribution as well as for purification to eliminate the impurities (Sinha et al.).

In contrast, post-synthesis assembly methods permit arranging nanotubes in a desired position without the need of high temperatures. Assembly methods also allow the choice of SWNT (e.g., commercially available SWNT) having properties suitable for the desired application. Different assembly methods that have been investigated so far include magnetic field (Long et al.) and electric field assisted assembly (Dimaki et al., Li et al., Seo et al., Chan et al., and Makaram et al.). However, previously available methods lack the scalability needed for high-rate manufacturing. For devices such as memories, assembly of the nanoelements needs to be performed over at least millimeter-square areas.

### SUMMARY OF THE INVENTION

One aspect of the invention is a method of fabricating an assembly of nanoelements in three dimensions. The method includes the steps of: a) providing an electrically insulating template in which to assemble the nanoelements; b) contacting the template with a liquid suspension of the nanoelements; and c) applying a voltage between a substrate attached to the template and the suspension. The template has a first surface, a second surface, and a plurality of nanoscale tunnels that connect between openings at the surfaces. The applied voltage causes nanoelements from the suspension to migrate into the tunnels by electrophoresis or dielectrophoresis. The method can be carried out at ambient temperatures and can be used to form nanoelement assemblies covering large areas of over 1 mm². In certain embodiments of the method the nanoelements are single walled carbon nanotubes.

Another aspect of the invention is a three-dimensional nanoelement assembly. The assembly includes an electrically conductive substrate attached to an electrically insulating template containing a plurality of nanoscale tunnels traversing between openings at first and second surfaces, and a plurality of nanoelements disposed within the tunnels. In certain embodiments of the assembly the nanoelements are single walled carbon nanotubes. In some embodiments the assembly forms an electrical interconnect for nanoscale electronic applications. In certain embodiments, the assembly functions as a Schottky diode or a p-n junction diode. In other embodiments, the assembly functions as a biosensor.

Yet another aspect of the invention is a microelectronic device that contains the nanoelement assembly. The device can be used, for example, as a memory, a switch, a microprocessor, an emitter, a solar cell, a display, or a biosensor. Still another aspect of the invention is a method of fabricating such an electronic device. The method includes the steps of providing an electronic device containing the nanoelement assembly and applying a contact layer to the template, whereby an electrically conductive pathway is established between the substrate and the contact layer through the nanoelement assembly.

### BRIEF DESCRIPTION OF THE DRAWINGS

FIG. 1 shows a schematic representation of a process of SWNT assembly according to the invention. A positive electrode is attached to a silicon substrate, which is attached to the underside of an alumina template, while a Pt—Ir wire in the SWNT suspension is used as the counter electrode.

FIG. 2 shows a schematic representation of one embodiment of a nanotube assembly according to the invention, with an equivalent electrical component diagram shown at the right.

FIGS. 3A and 3B show scanning electron micrographs of assembled SWNT in an anodic alumina array: FIG. 3A is a top view, and FIG. 3B is a cross-sectional view. The top layer is a contact layer of sputtered Au. The scale bars are 120 nm.

FIG. 4A shows I-V measurements of two different Si substrate-alumina template assemblies. The square data points represent a connection between SWNT assembled in the alumina template and a silicon substrate below the template. The round data points represent a control without assembled SWNT, and showing no current. FIG. 4B shows the current density as a function of voltage for a bulk Si-alumina assembly containing no nanotubes (triangles) and a Si-alumina assembly containing SWNT (squares).

### DETAILED DESCRIPTION OF THE INVENTION

The inventors have developed a method for assembling SWNT and other nanoelements into nanoporous templates utilizing electric field assisted assembly carried out at ambient temperatures. The method is scalable to at least several cm² and forms electrical connections capable of carrying high current density suitable for nanoscale electronics.

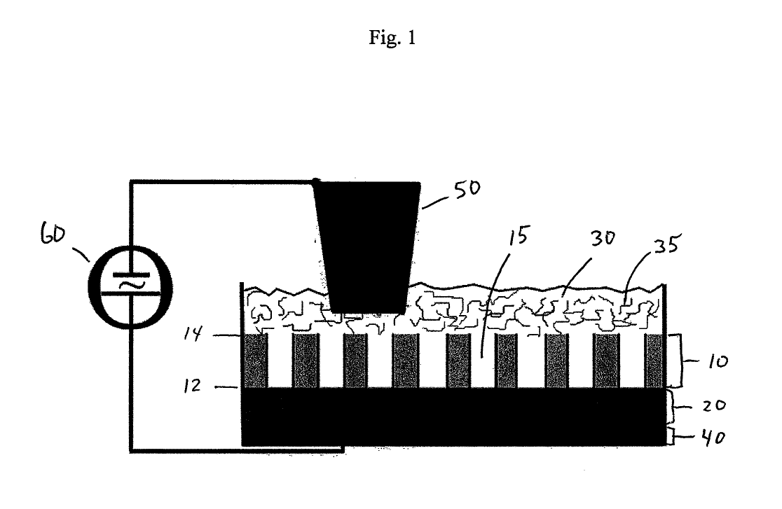

The invention provides a method for fabricating an assembly of nanoelements in three dimensions. The method will now be described with reference to the schematic drawing presented in FIG. 1. First, an electrically insulating template 10 is provided or prepared. The template is porous at the nanometer scale, and its porous nature is utilized to provide a preferred pathway in which the nanoelements will assemble in an appropriate electrical field. The template has a first surface 12, a second surface 14, and a plurality of nanoscale tunnels 15 that connect between openings at the first and second surfaces. The first surface of the template is in contact with an adjacent substrate 20, which contains a conducting or semiconducting material that provides electrical contact with the nanoelements. Optionally, the substrated is coated on a different surface with a layer of conducting material 40 serving as an electrical contact. The template is contacted at its second surface with a liquid suspension 30 containing nanoelements 35 or a mixture of nanoelements for assembly; the nanoelements are suspended in a solvent. Suitable solvents can be organic or inorganic solvents having a surface tension that is not greater than that of ethanol. Ethanol is a preferred solvent.

In order to drive nanoelement assembly, a voltage is applied between the substrate attached to the template (or electrical contact 40) and the suspension of nanoelements via suspension electrode 50 using voltage source 60. The substrate serves as one electrode, and a Pt or Pt—Ir wire or a metallic sheet or other structure placed into the suspension serves as the counter electrode. For example, the substrate can serve as the anode and the wire as the cathode, or alternatively the substrate can serve as the cathode and the wire as the anode. The voltage applied can be either DC, AC, or a combined DC+AC signal. For assembling SWNT a combination of DC and AC is preferred. An applied DC or AC voltage can be in the range from 0 to 100 kV, 0 to 1 kV, or 0 to 50 V, and the AC frequency can have any value from 0 to 500 MHz or 0 to 100 MHz. The applied voltage causes nanoelements from the suspension to align and migrate into the tunnels by electrophoresis or dielectrophoresis. The geometry of suspension electrode 50 should be such that a non-uniform electrical field is supplied over the surface of the template. For example, the electrode can be a wire or a pointed structure. Since assembly will occur over a limited range in the vicinity of the solution electrode, where the field is of sufficient strength, it may be required to move the solution electrode laterally across the template, i.e., parallel and in close proximity to the second surface, during application of the voltage to ensure uniform assembly over the entire surface of the template, or over a desired portion of the template.

The total force acting on a charged particle in solution is the sum of electrophoretic and dielectrophoretic forces F=F_{EP}+F_{DEp}. The electrophoretic force is F_{EP}=Γ∈ₘζE where, Γ is geometry factor, Eₘ relative permittivity of medium and ζ is the zeta-potential of particle. The dielectrophoretic force acting on a dielectric particle can be calculated as F_{DEP}=Λ∈ₚRe{k_{f}(ω)}|E|∇|E| where, Λ depends on the geometry, ∈ₚ relative permittivity of particle and k_{f} is Claussius-Mossotti factor depending both on geometry and frequency.

If a SWNT is considered as an ellipsoid, the electrophoretic force would not differ much from the spherical calculation except from the geometry factor, F. However, the dielectrophoretic force might change a lot depending on Claussius-Mossotti factor (Yang et al.), k_{f} (Yang et al.). k_{f} for an ellipsoid particle with a cylindrical symmetry could be written as k_{f}=Re{(∈ₚ^{*}−∈ₘ^{*})/3[(∈ₚ^{*}−∈ₘ^{*})A+∈ₘ^{*}]}, (Zheng et al.), where ∈ₚ^{*} and ∈ₘ^{*} are the complex permittivity of particle and medium respectively and A is the depolarizing factor given by A=(1−e²)/2e^{3[}1n((1+e)/(1−e))−2e]. e is defined as e≡\sqrt{1−(b/a)²}, where a and b are the major and minor axis of ellipsoid respectively.

For successful assembly, it is necessary to avoid allowing the charged nanotubes to stick on the positive electrode surface of the alumina template. For this reason an AC electric field can be used together with a DC field. The AC field does not contribute electrophoretic force and hence does not cause the nanotubes to move directly towards alumina surface. However, it helps them to orient and to move into the holes by resulting dielectrophoretic force.

Values of 2.5∈₀ and 10⁵ S m⁻¹ can be used for semiconducting nanotubes (s-SWNT) and −10⁴∈₀ and 10⁸ S m⁻¹ for metallic ones (m-SWNT), as the values of permittivity and conductivity respectively. ∈ and σ for ethanol is taken as 25∈₀ and 6 μSm⁻¹. By using these values the Claussius-Mossotti factor was estimated as k_{f}^{s-SWNT}=−0.3 and k_{f}^{m-SWNT}=−134 for electric field parallel to the major axis of nanotubes under DC field or low frequencies (including 10 MHz which is used in this experiment). These calculations show that actually metallic and semiconducting tubes migrate in the same direction, but the force on metallic nanotubes is 400 times larger than that acting on the semiconducting ones.

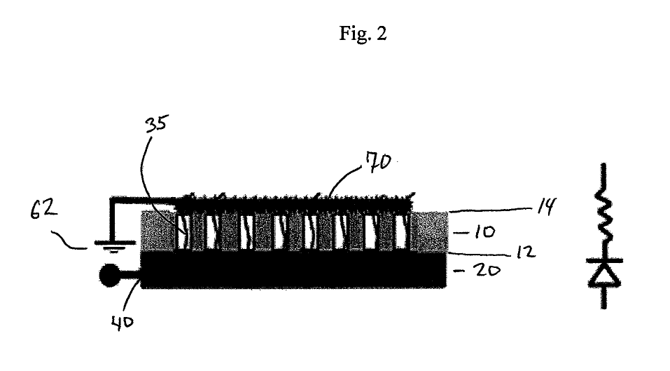

FIG. 2 depicts a circuit interconnect prepared from the above described nanoassembly. Following assembly of nanoelements 35 into the template 10 and removal of the residual nanoelement suspension (not shown), a layer 70 of a conductor, such as gold or another metal, can be deposited onto the second surface 14 of the template to provide electrical contact with the assembled nanoelements. Examples of suitable deposition techniques are sputtering and chemical vapor deposition. Electrical contact with the other end of the nanoelement assembly is provided through contact of the nanoelements with the substrate 20 at the first surface 12 of the template. Electrical circuit contact 40 is attached to the substrate; position of the attachment can vary depending on the needs of the application. Voltage source 62, which may be provided by a device that the circuit interconnect is installed in, connects electrical contacts 40 and 70 on the interconnect; the position of these contacts can be determined by the use of the interconnect and the device into which it is installed.

As used herein, the term “nanoscale” or “nanometer scale” refers to a structure having one or more dimensions in the range from about 1 nm to 1000 nm, and is used to distinguish from microscale structures having dimensions of greater than 1 μm.

### Substrate

Suitable substrates will typically be composed of a conducting or semiconducting material, or be coated with a conducting or semiconducting material. The substrate can be formed of a single homogeneous material or it can be formed from a layered assembly or other assembly of different materials. The substrate may or may not contain one or more base layers or other layers, such as an electrical contact layer or a layer to provide support or structure as required for use in a device. Such a layer can extend over the entire substrate surface or a portion of the substrate surface.

Any material suitable for use in nanodevices, electronics, photonics, or biosensor applications can be used in the substrate. For example, the substrate can contain silicon, silicon dioxide, a polymer, or other materials. For implementations involving electronics components, the substrate is preferably formed from a semiconductor material, such as doped silicon. A base layer or electrical contact can be formed by depositing a conducting metal such as gold, silver, copper, or chromium using known methods, such as evaporation or sputtering. The thickness of the base layer or contact layer, and any additional layers or regions, can be tailored to suit the desired application. Conducting layers will typically be in the nanometer range, e.g., from about 1 nm to about 1000 nm, or from about 1 nm to about 500 nm, or about 50 nm to about 150 nm, and preferably in the range from about 10 nm to about 100 nm, such as about 75 nm, but may be greater depending on the application.

### Nanoporous Template

According to the present method of assembling nanoelements such as SWNT, a nanoporous template is utilized to direct the assembly process in three dimensions and to provide points of contact with the substrate at a first surface of the template and with a another component, e.g., a circuit component, at a second surface of the template. The template contains a plurality of continuous pores or tunnels having a diameter in the nanometer range and extending from an opening at the first surface to an opening at the second surface. In this manner, nanoelements such as SWNT form a continuous pathway or connection, e.g., a circuit interconnect, between the substrate and another component. The template is stably adhered to the substrate and may cover all or just a portion of the substrate, depending on the application. The substrate surface on which the template is disposed can have any geometry, but is preferably planar. The template can have any desired geometry in a third dimension perpendicular to the surface or surface plane of the substrate, but preferably the template adopts the geometry and surface structure, including any surface texturing, of the substrate. Preferably the template is planar. The pores or tunnels of the template thus provide a connection in a third dimension leading away from the substrate surface, which is adjacent to the template first surface toward the connecting component, which is adjacent to the template second surface. The first and second surfaces of the template can be essentially parallel, or the first and second surfaces each can have different forms, e.g., one planar and the other textured. Preferably both template surfaces are planar and essentially parallel.

The template is fabricated from a material that is poorly conducting or essentially non-conducting. This serves to orient the electrical field during assembly so as to direct the migration of nanoelements into the template pores. A template for use in the invention can be prepared from, for example, aluminum oxide (alumina), titanium oxide, silicon oxide, non-conducting silicon, or a polymer. A variety of known nanofabrication techniques are available for fabricating a nanotemplate for use in the invention. See, e.g., Rabin et al., Matsumoto et al., and Gultepe et al. For example, the template can be fabricated by depositing a layer of desired material upon the substrate followed by a process such as photolithography, e-beam lithography, chemical etching, or an electrochemical process such as anodization to produce the pore structures. Pore structure and template morphology can be evaluated, for example, by electron microscopy or atomic force microscopy. A preferred fabrication method for the template is to anodize an Al film in the presence of 5 wt % oxalic acid, followed by soaking in a chromic-phosphoric acid solution, and repeated anodization in oxalic acid (Gultepe et al.). This process results in a hexagonally ordered array of tunnels having approximately 30 nm diameter, and extending through the entire thickness of the resulting Al₂O₃ layer, e.g., about 500 nm. Pore diameter can be enlarged as desired, e.g., to about 80 nm, by soaking the template in 5% phosphoric acid. However, any available method can be used that is capable of establishing a plurality of nanoscale tunnels. For example, in addition to chemical etching, the method can involve electron beam lithography (see Danelon et al., use of electron beam to prepare 50 nm holes in silicon nitride membranes; see also Chang et al., use of electron beam to prepare 50-200 nm holes in Si and Si oxide layers), electron beam lithography with reactive ion etching (see Storm et al., 20-200 nm holes in Si oxide), ion beam lithography, photolithography, or nanoimprint lithography.

The template contains a plurality nanoscale passageways (e.g., pores, channels, or tunnels, hereinafter generically referred to as “tunnels”) providing a connecting space between a first surface of the template and a second surface of the template. The tunnels have a diameter in the nanometer ranges, such as less than 1000 nm, less than 100 nm, less than 50 nm, less than 30 nm, or about 10-100 nm, 10-50 nm, 20-80 nm, or 1-10 nm. The length of the tunnels is generally determined by the thickness of the template, and can be any desired length, such as 10, 20, 30, 50, 80, 100, 200, 250, 500, 1000 nm or longer. Nanoscale tunnels in the template can be oriented so as to provide preferred pathways for nanoelement assembly. The tunnel orientation can be, for example, essentially vertical (e.g., perpendicular to the first and/or second surfaces of the template), extending continuously from one face of the template to the other. The tunnels can have any desired orientation with respect to one another. The tunnels can be essentially parallel to one another or can have different orientations. When considered from the first and/or second surfaces of the template, the tunnel openings can form a regular pattern or array, or can be distributed at random or according to any desired arrangement. The surface area of the first and second surfaces of the template can be in any desired range, but generally will be at least 0.1, 1, 2, 5, 10, 50, 100, 500, or 1000 or more mm². Larger surface area will provide greater current carrying capacity for a circuit interconnect prepared according to the invention. Usually, the current carrying capacity will be proportional to the template surface area (i.e., area of the first and/or second surfaces) as well as to the number and density of nanoelements bridging between the substrate and the connecting component, and thus also on the tunnel density (number per template surface area as well as cross-sectional area of tunnels per template surface area).

### Nanoelements

Any nanoelements can be assembled within the tunnels of a suitable template, provided that the nanoelements are either metallic, semiconducting, charged, or have dielectric properties that allows them to become charged in an electric field, so that they are capable of aligning and migrating by electrophoresis or dielectrophoresis. A mixture of different nanoelements having such properties also can be used. While nanoelements having various geometries (such as particulate, spherical, cylindrical, or tubular) will be suitable, their size should be somewhat smaller than the tunnel diameter of the template so as to permit assembly within the tunnels. Preferred nanoelements are nanotubes such as carbon nanotubes, single walled carbon nanotubes (SWNT), multiwalled carbon nanotubes, and nanospheres or nanobeads such as polystyrene or latex nanobeads. For circuit interconnect applications, SWNT are preferred due to their high conductivity. SWNT can be semiconducting or metallic, or a mixture thereof. A nanotube mixture used in the methods and devices of the invention preferably contains metallic SWNT.

### Devices

The above described method can be used to produce a three-dimensional nanoelement assembly, such as a circuit interconnect. The assembly includes an electrically conductive substrate attached to an electrically insulating nanoporous template. The template contains a plurality of nanoscale tunnels providing a pathway between openings at first and second surfaces of the template and a plurality of nanoelements assembled within the tunnels. In certain embodiments of the assembly the nanoelements are SWNT. The nanoelement assembly creates a three dimensional conductive pathway leading from the substrate to an electrical contact vertically removed from the substrate. The assembly forms an electrical interconnect for nanoscale electronic applications. When the interconnect includes a junction between a semiconducting substrate (e.g., p or n doped silicon) and metallic nanoelements (e.g., metallic SWNT), it functions as a Schottky diode. Alternatively, a p-n junction diode can be formed from the junction between p or n doped silicon and semiconducting SWNT. In other embodiments, the assembly can function as a biosensor. For example, nanotubes or nanoparticles in the assembly can be derivatized with probes such as polynucleotides (including nucleic acids and oligonucleotides), polypeptides (including peptides and proteins), antibodies (including polyclonal, monoclonal, single chain antibodies, single domain antibodies, or other recombinant antibodies), or pharmaceutical agents. Such assemblies can be used to detect biomolecules of interest in a sample, for example by causing an alteration of the conductivity or other electrical properties of the interconnect.

### Kits

The invention also includes kits containing one or more components of the invention together with packaging material and instructions for using the components. In one embodiment, a kit contains a substrate, a nanoporous template, and a suspension of nanoelements which the user assembles into a nanoassembly. In another embodiment, a kit contains a substrate with a bound nanoporous template, and the user supplies his own nanoelement solution. Yet another embodiment of a kit according to the invention is a nanoelement assembly containing a substrate and an attached nanoporous template containing assembled nanoelements. The kit also provides instructions for installing the assembly in a device provided by the user. A further embodiment of a kit includes a nanoporous template and a nanoelement solution. The user supplies a substrate, e.g., contained within the user's device, attaches the template to the substrate and uses the nanoelement suspension to prepare an assembly in the user's device.

In conclusion, nanoelements such as SWNT can be assembled vertically into nanoscale tunnels in a template by the combination of electrophoresis and dielectrophoresis. The method has many advantages, including mild conditions of assembly, use of post production or commercially available SWNT, high rate and large scale of assembly, and the integration of SWNT into silicon technology. It is also possible to attach aluminum oxide templates to Si after anodization if necessary, for example to avoid exposure to acidic environments (Jung et al.). Using nanoscale features in the templates, large scale assembly of SWNT, on the order of one million elements over a one centimeter square area, can be achieved. The strength of the connection established through the assembled SWNT is similar to the connection through nanotubes grown in place on Si. This assembly technique can be applied to make SWNT interconnects that integrate with Si microelectronics, such as in field emission displays and memory devices.

### EXAMPLES

### Example 1

### Preparation of a Nanoporous Alumina Template

Porous alumina nanotemplates were prepared on 0.1×0.1 cm² n-doped Si substrates (3-7 Ωcm). 1 μm thick Al was deposited by e-beam deposition on Si. Ordered nanoporous alumina templates were prepared by two step anodization (Matsuda et al., Li et al.) of the Al surface on the Si chip in 5 wt % oxalic acid. Anodization was carried out at 5 C under a constant 40 V DC potential until the whole Al layer was consumed (approx. 12 min). The resulting aluminum oxide barrier layer was removed by soaking in 5 wt % phorphoric acid for 40 min. The process produced a periodic, hexagonally-ordered nanoporous layer with pore diameter about 40 nm and thickness around 1 μm. The total area of alumina array was 0.4 cm².

### Example 2

### Preparation of a Three-Dimensional Assembly of SWNT

Negatively charged SWNT (Nantero, MA) were used for assembly into an alumina template prepared as described in Example 1. The SWNT solution was prepared in ethanol, and assembly occurred under 10V DC together with 10V AC at 10 MHz. A schematic of the assembly process can be seen in FIG. 1. The counter electrode was moved constantly to achieve assembly over large surface areas.

A pointed wire counter electrode was used for the assembly. This form of counter electrode can approach the template much closer, and the resulting electric field magnitude consequently is larger. The non-uniformity of the electric field is another reason for choosing a pointed electrode.

### Example 3

### Characterization of a Three-Dimensional Assembly of SWNT

The SWNT assembly from Example 2 was studied using scanning electron microscopy (SEM) and its current-voltage relationship was determined.

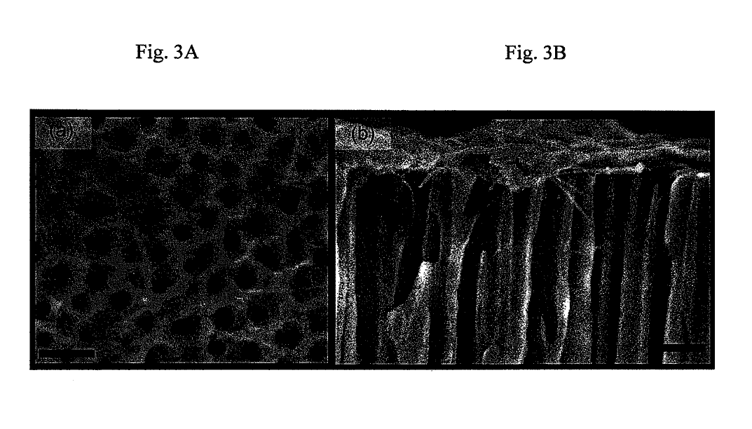

The SEM images of the assembly (FIG. 3) show that SWNT migrated into the holes. The SWNT also stayed partly on the surface since the length of SWNT was much larger than the template thickness. Although the size of individual SWNT is too small to be visible under SEM, it was possible to see SWNT bundles as shown at FIG. 3.

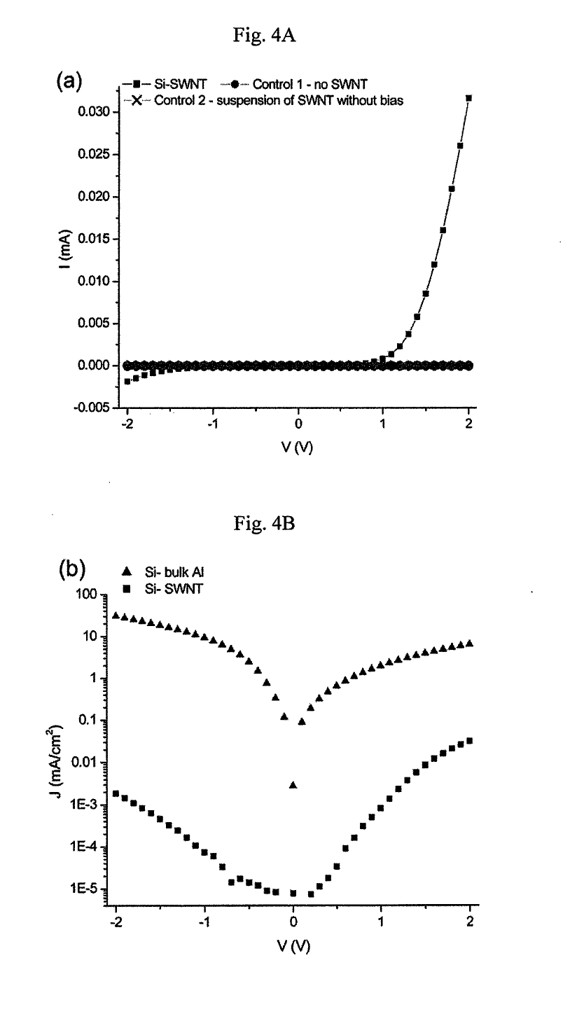

Since SEM was not an optimal technique for investigating the quality of the assembly, the current passing between the top and bottom layer of the assembly through assembled SWNT was also measured (FIG. 4A). The upper surface of the alumina template was sputtered with a 15 nm thick Au layer to form an electrical connection between all the SWNT on the surface. The I-V measurement was carried out using a parameter analyzer with a probe station by attaching one electrode to the Au layer and the other to the Si surface at the bottom of the template. The I-V curve of assembled SWNT showed a Schottky diode type behavior.

The I-V characteristics of a Schottky diode can be estimated by using the thermionic emission model (Cheung et al.). The practical non-ideal diode is usually modeled as a series combination of a diode and a resistor, R. The forward current passing over the diode can be expressed as I=Iₛexp[qV_{D}/nkT]; where IS depends only internal characteristics and effective area of the diode and temperature; q is the electronic charge, n is the ideality factor of diode, k Boltzmann constant, T is the absolute temperature and VD is the voltage across the diode, VD=V−IR. When the I-V curve of Au-SWNT-Si connection was fitted to a thermionic emission model, the resistance was found as RAu-SWNT-Si=17+/−3KΩ. A current density of 2 mA/cm² over assembled nanotubes was achieved per chip, which is the same as the current density observed previously observed over nanotubes grown in aluminum oxide templates by a high temperature synthesis method (Tzolov et al.). The current density reached over 5000 A/cm² when the estimated area of connection between only the SWNT and Si is used instead of the total chip area.

The SWNT used for assembly were a mixture of semiconducting and metallic types. Although calculations showed the force on the metallic SWNT is two orders of magnitude greater than on semiconducting SWNT, because of bundling of nanotubes, both types assembled into the tunnels. However the current passed preferentially over the metallic nanotubes because they are the lower resistant path, and also because there is no applied gate voltage. Hence, the observation of a Schottky barrier between Si and m-SWNT was consistent with theoretical predictions.

As a control measurement, an I-V curve was measured using the same template on a Si substrate, with the template covered by a Au layer but without the assembled SWNT. The results of the measurements can be seen in FIG. 4B. In the control experiment, since there were no SWNT to provide electrical connection, no current was observed between the top and bottom of the template.

### Example 4

### Preparation of a Three-Dimensional Assembly of Polystyrene Nanobeads

An aluminum oxide nanoporous template attached to a Si substrate was prepared by a method similar to that in Example 1 (see Gultepe et al.). The resulting template contained a hexagonal array of tunnels having a diameter of about 75-80 nm, with a template thickness of 250 nm, as determined by SEM. A suspension of 50 nm polystyrene beads was applied to the upper surface of the template. A DC voltage of 10 V was applied across the template (positive at the bottom of the template), producing a zeta potential of approximately −40 mV on the beads. After 2 minutes, the beads had migrated into and filled essentially all of the tunnels, as judged by SEM.

While the present invention has been described in conjunction with certain preferred embodiments, one of ordinary skill, after reading the foregoing specification, will be able to effect various changes, substitutions of equivalents, and other alterations to the compositions and methods set forth herein. It is therefore intended that the protection granted by Letters Patent hereon be limited only by the definitions contained in the appended claims and equivalents thereof.

### REFERENCES

1. D. S. Bethune, C. H. Kiang, M. S. de Vries, G. Gorman, R. Savoy, J. Vazquez and R. Beyers, Nature, 363, 605 (1993)
2. R. H. M. Chan, C. K. M. Fung and W. J. Li, Nanotechnology, 15, 5672 (2004)
3. H. Chang, S. M. Iqbal, E. A. Stach, A. H. King, N. J. Zaluzec, R. Bashir, Appl. Phys. Lett. 88, 103109 (2006)
4. S. K. Cheung and N. W. Cheung, Appl. Phys. Lett., 49, 85 (1986)
5. Y. Cho, H. M. Kim, T. W. Kang, J. J. Song, and W. Yang, Appl. Phys. Lett. 80, 1141 (2002)
6. C. Danelon, C. Santschi, J. Brugger, H. Vogel, Langmuir 22, 10711 (2006)
7. M. Dimaki and P. Boggild, Nanotechnology, 15, 1095 (2004)
8. T. Dürkop, S. A. Getty, E. Cobas, and M. S. Fuhrer, Nanoletters, 4, 35 (2004)
9. E. Gultepe, D. Nagesha, L. Menon, A. Busnaina, and S. Sridhar, Appl. Phys. Lett. 90, 163119 (2007)
10. W. Hu, D. Gong, Z. Chen, L. Yuan, K. Saito, C. A. Grimes and P. Kichambare, Appl. Phys. Lett., 79, 3083 (2001)
11. S. Hwang, J. Lee, S. Jeong, P. Lee and K. Lee, Nanotechnology, 16, 850 (2005)
12. H. Y. Jung, S. M. Jung, G. H. Gu, and J. S. Suh, Appl. Phys. Lett, 89, 013121 (2006)
13. J. Kong, H. T. Soh, A. M. Cassell, C. F. Quate and H. Dai, Nature, 395, 878 (1998)
14. C. Li, I. V. Roshchin, X. Batlle, M. Viret, F. Ott, and I. K. Schuller, J. Applied Physics, 100, 074318 (2006)
15. J. Li, C. Papadopoulos and J. Xu, Nature, 402, 253 (1999)
16. J. Li, Q. Zhang, N. Peng, and Q. Zhu, Appl. Phys. Lett. 86, 153116 (2005)
17. D. P. Long, J. L. Lazorcik and R. Shashidhar, Adv Mater, 16, 814 (2004)
18. P. Makaram, S. Selvarasah, X. Xiong, C. Chen, A. Busnaina, N. Khanduja and M. R. Dokmeci, Nanotechnology, 18, 395204, (2007)
19. H. Masuda and K. Fukuda, Science, 268, 1466 (1995)
20. F. Matsumoto, M. Harada, K. Nishio and H. Masuda, Adv. Mater., 17, 1609 (2005)
21. O. Rabin, P. R. Herz, Y.-M. Lin, A. I. Akinwande, S. B. Cronin and M. S. Dresselhaus, Adv. Func. Mater., 13, 631 (2003)
22. H. Seo, C. Han, D. Choi, K. Kim and Y. Lee, Microelec. Eng., 81, 83 (2005)
23. N. Sinha, J. Ma and J. T. W. Yeow, J. Nanosci. Nanotechnol., 6, 573 (2006)
24. A. J. Storm, J. H. Chen, X. S. Ling, H. W. Zandbergen, C. Dekker, Nature Materials 2, 537 (2003)
25. M. Tzolov, B. Chang, A. Yin, D. Straus and J. M. Xu, Phys. Rev. Lett., 92, 075505 (2004)
26. M. Yang and X. Zang, Sensors and Actuators A, 135, 73 (2007)
27. Z. Yao, C. L. Kane and C. Dekker, Phys. Rev. Lett., 84, 2941 (2000)
28. L. Zheng, J. P. Brody and P. J. Burke, Biosensors and Bioelectronics, 20, 606 (2004)

1. A method of fabricating an assembly of nanotubes in three dimensions, the method comprising the steps of:
a) providing an electrically insulating template comprising a first surface, a second surface, and a plurality of nanoscale tunnels, wherein the first surface is attached to an electrically conductive substrate, and each tunnel extends from an opening at the first surface to an opening at the second surface;
b) contacting the second surface of the template with a liquid suspension of said nanotubes; and
c) applying a voltage between the substrate and the suspension, wherein the voltage is the sum of a DC voltage and an AC voltage, whereby nanotubes from the suspension migrate into the tunnels and assemble therein.

2. The method of claim 1, wherein the substrate comprises silicon.

3. The method of claim 1, wherein the template comprises a material selected from the group consisting of aluminum oxide, titanium oxide, silicon oxide, and non-conducting silicon.

4. The method of claim 1, wherein each of said first and second surfaces has a surface area of at least 1 mm².

5. (canceled)

6. The method of claim 1, wherein the assembly process comprises a combination of electrophoresis and dielectrophoresis.

7. The method of claim 1, wherein the substrate serves as a cathode and an electrode placed into the suspension serves as an anode.

8. The method of claim 1, wherein the substrate serves as an anode and an electrode placed into the suspension serves as a cathode.

9. The method of claim 1, wherein an electrode in the suspension is moved laterally across the second surface of the template during application of the voltage.

10. The method of claim 1, wherein an electrode in the suspension has a shape that provides a non-uniform electrical field.

11. The method of claim 1, wherein the step of applying a voltage is carried out at a temperature less than 30 C.

12. The method of claim 1, wherein the nanotubes comprise carbon nanotubes, single-walled carbon nanotubes, metallic nanotubes, or dielectric nanotubes.

13. The method of claim 12, wherein the nanotubes comprise single walled carbon nanotubes and the substrate comprises silicon.

14. The method of claim 1, wherein the suspension comprises an organic or inorganic solvent having a surface tension not greater than that of ethanol.

15. A nanotube assembly comprising:
an electrically conductive substrate;
an electrically insulating template comprising a first surface, a second surface, and a plurality of nanoscale tunnels, wherein the first surface is attached to the substrate, and each tunnel extends from an opening at the first surface to an opening at the second surface; and
a plurality of nanotubes disposed within said tunnels.

16. The nanotube assembly of claim 15, wherein the nanotubes are metallic or semiconducting and form an electrically conductive junction with the substrate.

17. The nanotube assembly of claim 16, wherein the nanotubes are metallic and the substrate is semiconducting, and wherein the assembly functions as a Schottky diode.

18. The nanotube assembly of claim 16, wherein the nanotubes are semiconducting and the substrate is semiconducting, and wherein the assembly functions as a p-n junction diode.

19. The nanotube assembly of claim 15, wherein each of said first and second surfaces has a surface area of at least 1 mm².

20. The nanotube assembly of claim 15, wherein the substrate comprises silicon.

21. The nanotube assembly of claim 15, wherein the template comprises a material selected from the group consisting of aluminum oxide, titanium oxide, silicon oxide, and non-conducting silicon.

22. The nanotube assembly of claim 15 which functions as a three-dimensional circuit interconnect.

23. The nanotube assembly of claim 15, wherein the nanotubes are linked to a moiety selected from a polynucleotide, a polypeptide, an antibody, or a pharmaceutical agent.

24. The nanotube assembly of claim 15 further comprising a contact layer applied to the second surface of the template.

25. The nanotube assembly of claim 16, wherein the substrate comprises silicon and the nanotubes comprise single walled carbon nanotubes, and wherein the substrate-nanotube connection carries a current density of at least 300 A/cm² at 2 V bias.

26. A microelectronic device comprising the nanotube assembly of claim 15.

27. The device of claim 26 which is a memory, a switch, a microprocessor, an emitter, a solar cell, a display, or a biosensor.

28. A method of fabricating an electronic device, the method comprising:
a) providing an electronic device comprising the nanotube assembly of claim 16; and
b) applying a contact layer to the second surface of the template, whereby an electrically conductive pathway is established between the substrate and the contact layer through the nanotube assembly.
